(19) United States
(12) Patent Application Publication
(10) Pub. No.: US 2012/0192943 A1
(43) Pub. Date: Aug. 2, 2012

(54) FABRICATION METHOD FOR LOCAL BACK CONTACT PHOTOVOLTAIC CELLS

(75) Inventors: Bart Vermang, Leuven (BE); Hans Goverde, Eindhoven (NL)

(73) Assignees: Katholieke Universiteit Leuven, Leuven (BE); IMEC, Leuven (BE)

(21) Appl. No.: 13/361,747

(22) Filed: Jan. 30, 2012

Related U.S. Application Data
(60) Provisional application No. 61/462,350, filed on Jan. 31, 2011.

(51) Int. Cl. H01L 31/0224; H01L 31/02

(52) U.S. Cl. 136/256; 438/98; 257/E31.113

(57) ABSTRACT

A method is disclosed for fabricating a photovoltaic cell comprising local back contacts. In one aspect, the method includes providing a silicon substrate, depositing a surface passivation layer at a rear side of the silicon substrate, forming delaminated regions or bubbles at an interface between the surface passivation layer and the silicon substrate, depositing a metal layer on the surface passivation layer, and performing a metal firing.

### CROSS REFERENCE TO RELATED APPLICATIONS

This application claims priority under 35 U.S.C. §119(e) to U.S. provisional patent application 61/462,350 filed on Jan. 31, 2011, which application is hereby incorporated by reference in its entirety.

### BACKGROUND OF THE INVENTION

1. Field of the Invention

The disclosed technology relates to photovoltaic cells, and more in particular, to a method of manufacturing photovoltaic cells with local back contacts and photovoltaic cells thus obtained.

2. Description of the Related Technology

Advanced device structures have been developed for crystalline silicon photovoltaic cells with local back contacts, such as passivated emitter and rear cell (PERC) and passivated emitter rear locally diffused cell (PERL) structures. Such advanced device structures lead to higher energy conversion efficiencies but require more process steps and thus result in a higher fabrication cost as compared to less advanced structures.

There is a need for a reduction of the cost per Watt peak of crystalline silicon photovoltaic cells, for example by reducing the fabrication cost and at the same maintaining good energy conversion efficiencies.

### SUMMARY OF CERTAIN INVENTIVE ASPECTS

A first inventive aspect relates to a method for fabricating silicon photovoltaic cells with local back contacts, wherein the number of process steps is reduced as compared to prior art fabrication methods and thus the manufacturing cost is reduced, and wherein the method allows fabricating local back contact cells with a good open-circuit voltage and a good short-circuit current, resulting in good energy conversion efficiencies.

A method is disclosed for fabricating a photovoltaic cell comprising local back contacts, the method comprising providing a silicon substrate, depositing a surface passivation layer at a rear side of the silicon substrate, forming delaminated regions, e.g. bubbles, at an interface between the surface passivation layer and the silicon substrate, depositing a metal layer on the surface passivation layer, and performing a metal firing.

Thereby a conductive path is formed between the metal layer and the silicon substrate at the location of the delaminated regions, resulting in back contacts for the photovoltaic cell or device.

Advantageously, forming delaminated regions, e.g. bubbles, at an interface between the surface passivation layer and the silicon substrate comprises: cleaning the silicon substrate using a hydrophobic cleaning method; depositing the surface passivation layer at a rear side of the silicon substrate after hydrophobic cleaning; and performing a thermal treatment.

One inventive aspect relates to a method for fabricating silicon photovoltaic cells with local back contacts, wherein the method comprises a) providing a silicon substrate, b) cleaning the silicon substrate using a hydrophobic cleaning method, c) after hydrophobic cleaning, depositing a surface passivation layer at a rear side of the silicon substrate, the surface passivation layer having a thickness of, for example, at least about 30 nm, d) performing a thermal treatment at a temperature in the range, for example, between about 400° C. and 600° C., thereby forming delaminated regions, e.g. bubbles, at an interface between the surface passivation layer and the silicon substrate, e) depositing a metal layer on the surface passivation layer, and f) performing a metal firing. During the metal firing, local back contacts are formed at the location of the delaminated regions. Thus, local back contacts are formed without the need for making openings in the surface passivation layer before depositing the metal layer. It is believed that the contacts may be formed due to microscopic cracks in the bubbles or blisters, which allow penetration of the metal within the blister and towards the silicon substrate.

In one aspect, a hydrophobic cleaning method is a cleaning method leaving a hydrophobic surface after cleaning. For example, a hydrophobic cleaning method may comprise performing a dip in diluted HF as a last step.

The surface passivation layer can be a single layer or a stack of layers comprising at least a first layer (deposited on the silicon substrate) and a second layer (deposited on the first layer). In embodiments wherein the surface passivation layer is a single layer, it can for example be an Al₂O₃ layer having a thickness of at least about 30 nm. In embodiments wherein the surface passivation layer is a stack of layers, the first layer can for example be an Al₂O₃ layer, e.g. with a thickness in the range between about 2 nm and 30 nm, e.g. between about 5 nm and 15 nm, and the second layer can for example be a SiNₓ layer and/or a SiOₓ layer, e.g. with a thickness in the range between about 70 nm and 300 nm, e.g. between about 100 nm and 200 nm. The Al₂O₃ layer can for example be provided by thermal atomic layer deposition (ALD), plasma enhanced ALD, plasma enhanced chemical vapor deposition (CVD), or by any other suitable method known by a person skilled in the art. In certain embodiments, a thermal ALD Al₂O₃ layer may be deposited at a temperature lower than about 250° C., such as between about 200° C. and 250° C. The second layer can be deposited by CVD, particularly at a temperature in the range between about 400° C. and 600° C., thereby at the same time performing the thermal treatment and avoiding the need for a separate thermal treatment. The metal layer deposited on the surface passivation layer can for example comprise Al. The metal firing induces the formation of local contacts at the location of delaminated regions. The metal firing step may be performed at a temperature larger than about 835° C., e.g. at a temperature in the range between about 835° C. and 950° C.

In one inventive aspect, the method can further comprise a step of introducing surface features on the rear surface of the silicon substrate in order to control position and/or density of the formation of delaminated regions or bubbles.

In one inventive aspect wherein the surface passivation layer is a stack of layers, the method can further comprise performing an additional annealing step after depositing the first layer and before depositing the second layer, the additional annealing step being adapted for outgassing the first layer, thereby avoiding the formation of a second type of delaminated regions when firing the metal. Preferably, the additional annealing step is performed at a temperature in the range between about 600° C. and 900° C., e.g. between 600° C. and 800° C. This additional annealing can for example be done in a forming gas atmosphere or in an inert atmosphere such as a nitrogen atmosphere, for example with a duration of about 20 minutes to 1 hour, such as about 30 minutes.

It is an advantage of a method according to one inventive aspect that the metal firing step leads to the formation of local rear side contacts without the need for providing openings in the surface passivation layer before providing the metal layer. Thus the number of process steps is reduced and the manufacturing throughput is increased as compared to prior art fabrication processes for photovoltaic cells with local back contacts.

It is an advantage of a method according to one aspect that the Al₂O₃ layer can be deposited at a low temperature (e.g. about 200° C.), leading to a better surface passivation quality as compared to Al₂O₃ layers deposited at higher temperatures.

A second inventive aspect relates to the use of the method according to the first aspect for forming local back contacts of the photovoltaic cells at the location of the delaminated regions, e.g. bubbles.

A third inventive aspect relates to a photovoltaic device having a rear surface and a front surface, the photovoltaic device comprising a silicon substrate, a surface passivation layer at a rear side of the silicon substrate and local back contacts, wherein the local back contacts are randomly distributed on the rear surface of the photovoltaic device.

The local back contacts being randomly distributed means that any predetermined position of any of the back contacts, or predetermined regularity or periodicity in the positions of the back contacts is absent.

According to preferred embodiments, the passivation layer comprises delaminated regions at positions corresponding to the local back contacts.

According to preferred embodiments, the passivation layer has a thickness of at least 30 nm.

According to preferred embodiments, the passivation layer comprises a first layer comprising Al₂O₃, with a thickness in the range between about 2 nm and 30 nm, and a second layer comprising SiNₓ and/or SiOₓ, with a thickness in the range between about 70 nm and 300 nm.

Certain objects and advantages of certain inventive aspects have been described herein above. Of course, it is to be understood that not necessarily all such objects or advantages may be achieved in accordance with any particular embodiment of the disclosure. Thus, for example. those skilled in the art will recognize that the disclosure may be embodied or carried out in a manner that achieves or optimizes one advantage or group of advantages as taught herein without necessarily achieving other objects or advantages as may be taught or suggested herein. Further, it is understood that this summary is merely an example and is not intended to limit the scope of the disclosure. The disclosure, both as to organization and method of operation, together with features and advantages thereof, may best be understood by reference to the following detailed description when read in conjunction with the accompanying drawings.

### BRIEF DESCRIPTION OF THE DRAWINGS

FIG. 1 is a microscope picture of a thermal ALD Al₂O₃ layer capped with PECVD SiNₓ.

FIG. 2 is SEM picture (cross section) of a partially delaminated ALD Al₂O₃/PECVD SiNₓ stack.

FIG. 3 shows optical microscope pictures of CZ Si substrates at different stages: FIG. 3(a) after ALD deposition of 5 nm Al₂O₃; FIG. 3(b) after ALD deposition of 5 nm Al₂O₃ and annealing in a nitrogen atmosphere at 550° C.; and FIG. 3(c) after ALD deposition of 5 nm Al₂O₃, annealing in a nitrogen atmosphere at 550° C. and SiNₓ deposition.

FIG. 4 shows optical microscope pictures of CZ Si substrates at different stages: FIG. 4(a) after ALD deposition of 30 nm Al₂O₃; FIG. 4(b) after ALD deposition of 30 nm Al₂O₃ and annealing in Forming Gas at 350° C.; and FIG. 4(c) after ALD deposition of 30 nm Al₂O₃, annealing in a Forming Gas at 350° C. and SiNₓ deposition.

FIG. 5 shows optical microscope pictures of CZ Si substrates at different stages: FIG. 5(a) after ALD deposition of 30 nm Al₂O₃ and annealing in nitrogen at 350° C.; and FIG. 5(b) after ALD deposition of 30 nm Al₂O₃, annealing in nitrogen at 350° C. and SiNₓ deposition.

FIG. 6 shows optical microscope pictures of CZ Si substrates at different stages: FIG. 6(a) after ALD deposition of 30 nm Al₂O₃ and annealing in nitrogen at 550° C.; and FIG. 6(b) after ALD deposition of 30 nm Al₂O₃, annealing in nitrogen at 550° C. and SiNₓ deposition.

FIG. 7 is SEM picture (cross section) of a local contact (with back surface field) formed after firing an Al metal layer on top of a delaminated region.

FIG. 8 shows a comparison chart between a process flow according to one embodiment and alternative, state of the art process flows.

FIG. 9 shows (a) SEM tilted top-view and (b) cross-section images of a blistered ALD Al₂O₃/PECVD SiNₓ layer on a mirror-polished c-Si substrate. FIG. 9(c) and FIG. 9(d) are optical microscopy top-view pictures of an ALD Al₂O₃/PECVD SiNₓ layer grown on a rough c-Si surface, for a hydrophilic pre-ALD deposition clean (FIG. 9(c)) and a hydrophobic pre-ALD deposition clean (FIG. 9(d)).

FIG. 10 is a schematic representation of the mechanism of semiconductor-metal contact formation by firing a blistered passivation layer covered by an Al layer.

FIG. 11(a) shows the average blistering radius measured for a stack comprising a 5 nm, 10 nm or 30 nm thick ALD Al₂O₃ layer and a PECVD SiNₓ layer, before and after co-firing. The pre-ALD wafer cleaning was hydrophilic (Si—OH) or hydrophobic (Si—H).

FIG. 11(b) shows the average short-circuit current density (J_{sc}) and open-circuit voltage (V_{oc}) and FIG. 11(c) depicts the average fill factor (FF) and efficiency (eta) for random Al BSF Si solar cells passivated at the rear side by the same Al₂O₃/SiNₓ layers as in FIG. 11(a). In all cases the peak firing temperature was 865° C.

FIG. 12 shows a LBIC mapping (20 μm resolution) of a random Al BSF solar cell part, clearly showing the random metal-semiconductor contacts at the rear.

FIGS. 13(a), 13(b), 13(c) and 13(d) show respectively the average J_{sc}, V_{oc}, FF and cell efficiency for Al₂O₃/SiNₓ rear passivated random Al BSF Si solar cells as a function of peak firing temperature. The pre-Al₂O₃ cleaning was hydrophobic and the Al₂O₃ thickness was 5 nm, 10 nm or 30 nm. Also the average cell characteristics for a reference full Al BSF cell are indicated.

FIGS. 14(a) and 14(b) illustrate a process flow according to one embodiment wherein contacts are formed at the location of blisters in the passivation layer. FIG. 14(a) comprises images of real samples, while FIG. 14(b) is a schematic representation of the same flow.

In the different drawings, the same reference signs refer to the same or analogous elements.

### DETAILED DESCRIPTION OF CERTAIN ILLUSTRATIVE EMBODIMENTS

In the following detailed description, numerous specific details are set forth in order to provide a thorough understanding of the disclosure and how it may be practiced in particular embodiments. However, it will be understood that the present disclosure may be practiced without these specific details. In other instances, well-known methods, procedures and techniques have not been described in detail, so as not to obscure the present disclosure. While the present disclosure will be described with respect to particular embodiments and with reference to certain drawings, the disclosure is not limited hereto. The drawings included and described herein are schematic and are not limiting the scope of the disclosure. It is also noted that in the drawings, the size of some elements may be exaggerated and, therefore, not drawn to scale for illustrative purposes.

Furthermore, the terms first, second, third and the like in the description, are used for distinguishing between similar elements and not necessarily for describing a sequence, either temporally, spatially, in ranking or in any other manner. It is to be understood that the terms so used are interchangeable under appropriate circumstances and that the embodiments of the disclosure described herein are capable of operation in other sequences than described or illustrated herein.

Moreover, the terms top, bottom, over, under and the like in the description are used for descriptive purposes and not necessarily for describing relative positions. It is to be understood that the terms so used are interchangeable under appropriate circumstances and that the embodiments of the disclosure described herein are capable of operation in other orientations than described or illustrated herein.

It is to be noticed that the term “comprising” should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B.

In certain embodiments, the front surface or front side of a photovoltaic cell or of a substrate is the surface or side adapted for being oriented towards a light source and thus for receiving illumination. The back surface, rear surface, back side or rear side of a photovoltaic cell or of a substrate is the surface or side opposite to the front surface or side.

A “delaminated region” refers to a region which is delaminated, as for instance a bubble or a blister. For the purpose of the present description, the terms “bubble” and “blister” are used as synonyms.

One embodiment relates to a method for the fabrication of photovoltaic cells with local back contacts, wherein the method comprises: providing a silicon substrate; cleaning the silicon substrate using a hydrophobic cleaning method; after hydrophobic cleaning, providing at a rear side of the silicon substrate a surface passivation layer, the surface passivation layer having a thickness of at least about 30 nm, for example a thickness in the range between about 30 nm and 150 nm; and performing a thermal treatment at a temperature in the range between about 400° C. and 600° C. This results in the formation of delaminated regions, e.g. bubbles, at the interface between the semiconductor substrate and the surface passivation layer. The surface passivation layer can comprise a single layer or it can comprise a stack of at least a first layer and a second layer. In embodiments wherein the surface passivation layer comprises at least a first layer and a second layer, the deposition of the second layer can also have the function of the thermal treatment. The thickness of the surface passivation layer can be selected for providing a good back reflection in addition to providing a good rear surface passivation quality. The method further comprises providing a metal layer, e.g. an Al layer, covering the surface passivation layer at the rear side and performing a metal firing step, thereby forming rear contacts and rear BSF regions in the delaminated regions. Providing the metal layer can comprise screen printing, sputtering, evaporation or any other suitable method known to a person skilled in the art. Performing the metal firing step is preferably done at a temperature higher than about 835° C., e.g. at a temperature in the range between about 835° C. and 950°, for example between about 850° C. and 900° C.

In certain embodiments, the surface passivation layer can for example comprise an Al₂O₃ layer. In embodiments wherein the surface passivation layer is a single layer, the thickness of the Al₂O₃ layer is at least about 30 nm. In embodiments wherein the surface passivation layer is a stack of layers, the Al₂O₃ layer is provided as a first layer on the rear side of the silicon substrate and a second layer is provided on the first layer. The total thickness of the first layer and the second layer is preferably at least about 100 nm.

The Al₂O₃ layer can for example be provided by ALD, e.g. thermal ALD or plasma enhanced ALD. However, the present disclosure is not limited thereto and other suitable methods known by a person skilled in the art can be used. In one embodiment the ALD Al₂O₃ layer is deposited at a temperature lower than about 250° C., e.g. using H₂O and TMA as precursors. The second layer can for example be a SiNₓ layer or a SiOₓ layer or any other suitable layer known by a person skilled in the art. The second layer can for example be deposited by a chemical vapor deposition (CVD) method, particularly at a temperature in the range between about 400° C. and 600° C.

It is an advantage of a method according to one embodiment as compared to prior art fabrication methods for photovoltaic cells with local back contacts that the need for creating openings in the rear surface passivation stack before providing the rear metal layer for enabling the formation of local metal contacts can be avoided. Instead, during the metal firing step, local contacts are formed in the delaminated regions.

It has been shown that Al₂O₃ layers, e.g. deposited by means of ALD techniques, provide a very good passivation for p-type silicon. This excellent passivation quality is related to chemical passivation and field effect passivation. The best ALD Al₂O₃ passivation quality is obtained at low deposition temperatures (e.g. about 200° C.).

Layers deposited at this low temperature also reveal ‘blisters’ or ‘bubbles’, caused by partial delamination if a critical thickness of the passivation layer (e.g. about 30 nm for an Al₂O₃ layer, e.g. about 100 nm for a stack comprising an Al₂O₃ layer and a SiNₓ layer) and a critical temperature (e.g. about 400° C. to 600° C.) are reached. Partial delamination may for example be related to stress built up in the Al₂O₃ layer or may be related to hydrogen release in the Al₂O₃ layer upon a thermal treatment above the critical temperature. In a method according to one embodiment, this partially delaminated passivation layer is used as rear surface passivation layer for PERC-type solar cells. The delaminated regions become local point contacts after firing of the rear metal. In addition, firing of the rear metal results in the formation of a local Back Surface Field.

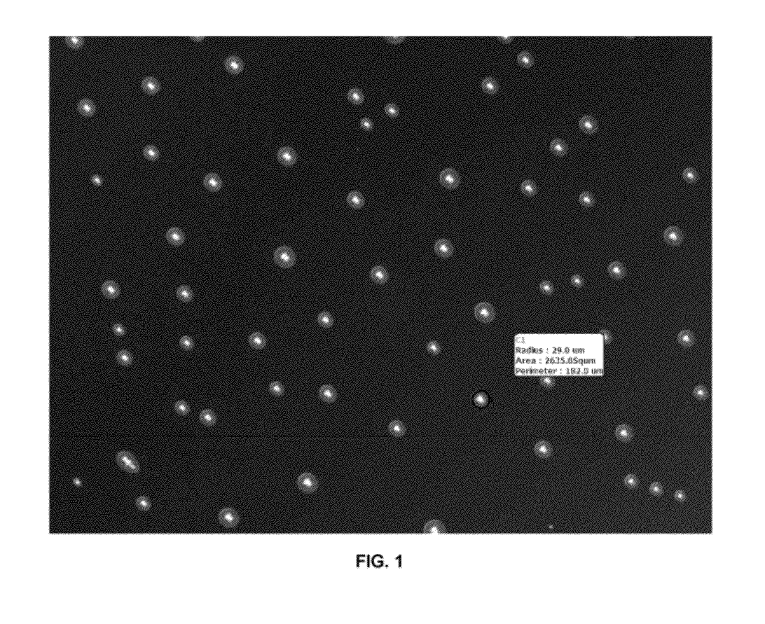

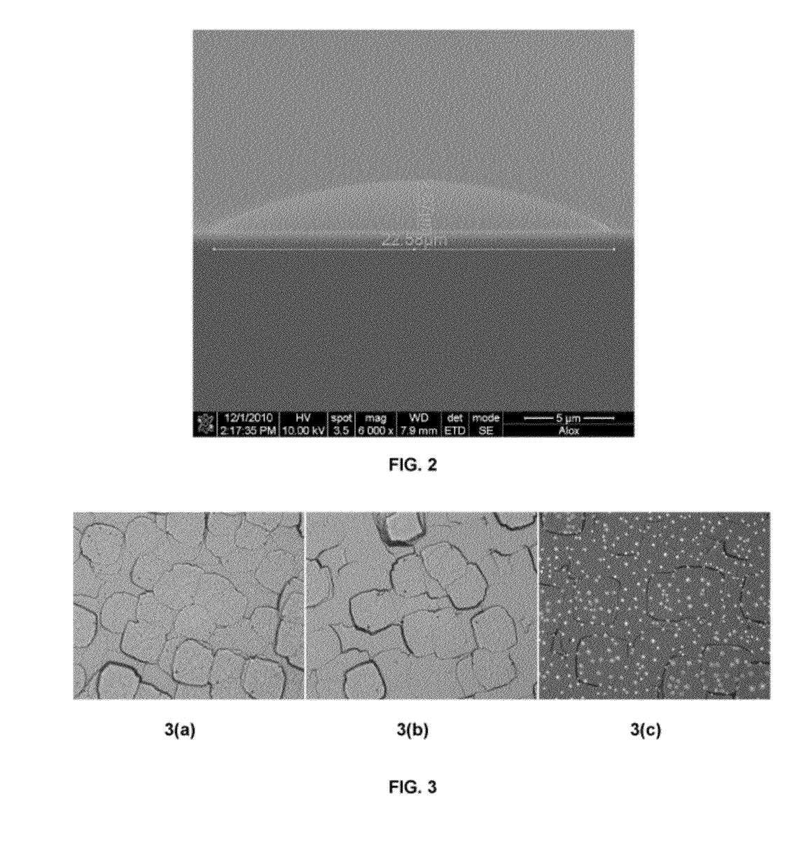

FIG. 1 is a microscope picture (top view) of a surface passivation layer comprising an about 30 nm thick thermal ALD Al₂O₃ layer capped with a 100 nm thick PECVD SiNₓ layer, deposited on a hydrophobically cleaned mirror-polished silicon substrate. The thermal ALD Al₂O₃ layer was deposited at 200° C. using H₂O and TMA as precursors. FIG. 2 is SEM picture (cross section) of the partially delaminated ALD Al₂O₃/PECVD SiNₓ stack of FIG. 1. It can be seen that the partial delamination results in the formation of a bubble, in the example shown having a diameter of 22.6 micrometer.

FIG. 3 shows optical microscope pictures of CZ Si substrates at different stages: FIG. 3(a) after ALD deposition of 5 nm Al₂O₃; FIG. 3(b) after ALD deposition of 5 nm Al₂O₃ and annealing in a nitrogen atmosphere at 550° C.; and FIG. 3(c) after ALD deposition of 5 nm Al₂O₃, annealing in a nitrogen atmosphere at 550° C. and SiNₓ deposition at 420° C. (SiNₓ layer thickness 200 nm to 300 nm).

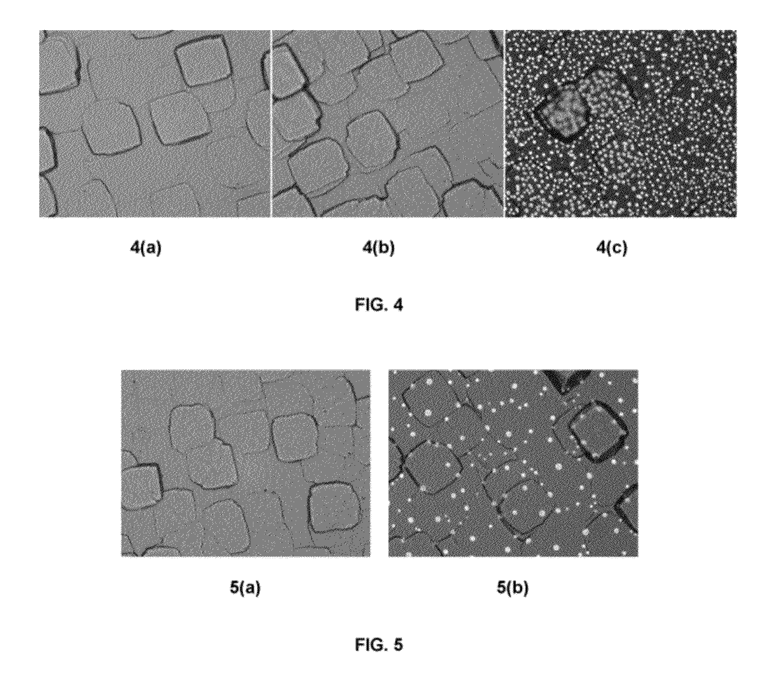

FIG. 4 shows optical microscope pictures of CZ Si substrates at different stages: FIG. 4(a) after ALD deposition of 30 nm Al₂O₃; FIG. 4(b) after ALD deposition of 30 nm Al₂O₃ and annealing in Forming Gas at 350° C.; and FIG. 4(c) after ALD deposition of 30 nm Al₂O₃, annealing in a Forming Gas at 350° C. and SiNₓ deposition at 420° C. (SiNₓ layer thickness 200 nm to 300 nm).

FIG. 5 shows optical microscope pictures of CZ Si substrates at different stages: FIG. 5(a) after ALD deposition of 30 nm Al₂O₃ and annealing in nitrogen at 350° C.; and FIG. 5(b) after ALD deposition of 30 nm Al₂O₃, annealing in nitrogen at 350° C. and SiNₓ deposition at 420° C. (SiNₓ layer thickness 200 nm to 300 nm).

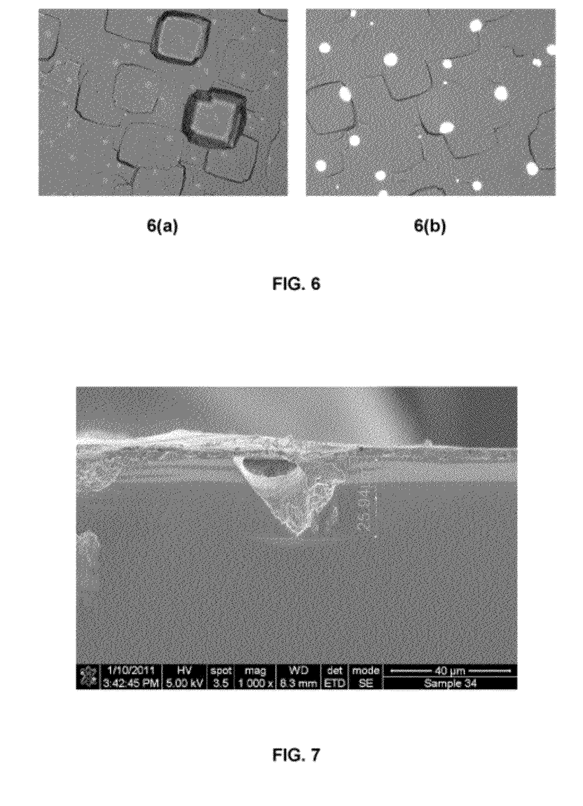

FIG. 6 shows optical microscope pictures of CZ Si substrates at different stages: FIG. 6(a) after ALD deposition of 30 nm Al₂O₃ and annealing in nitrogen at 550° C.; and FIG. 6(b) after ALD deposition of 30 nm Al₂O₃, annealing in nitrogen at 550° C. and SiNₓ deposition at 420° C. (SiNₓ layer thickness 200 nm to 300 nm).

For all the samples shown in FIG. 3, FIG. 4, FIG. 5 and FIG. 6 a hydrophobic cleaning (2% HF dip as a last step) of the silicon substrate was performed before Al₂O₃ deposition. From the results shown in FIG. 3, FIG. 4, FIG. 5 and FIG. 6, it can be concluded that the formation of delaminated regions and the size and density of the delaminated regions are influenced by several parameters, such as the thickness of the Al₂O₃ layer, the ambient of the thermal treatment or annealing, the temperature of the thermal treatment, and the presence of a SiNₓ layer on top of the Al₂O₃ layer.

For example, comparing FIG. 3(c) with FIG. 6(b), there is a difference in the thickness of the Al₂O₃ layer, being 5 nm for the sample shown in FIG. 3(c) and 30 nm for the sample shown in FIG. 6(b). For the thicker Al₂O₃ layer the number of bubbles is smaller and they have a larger size. In FIG. 6(a) it can be seen that for a 30 nm thick Al₂O₃ layer bubble formation starts after annealing and before SiNₓ deposition.

For example, comparing FIG. 4(c) with FIG. 5(b), there is a difference in the ambient of the thermal treatment, being Forming Gas for the sample shown in FIG. 4(c) and nitrogen for the sample shown in FIG. 5(b). The number of bubbles is smaller and they have a larger size when the thermal treatment is performed in nitrogen.

For example, comparing FIG. 5(b) with FIG. 6(b), there is a difference in the temperature of the thermal treatment, being 350° C. for the sample shown in FIG. 5(b) and 550° C. for the sample shown in FIG. 6(b). The number of bubbles is smaller and their size is larger for the higher annealing temperature. Also, for the higher annealing temperature the formation of delaminated regions already starts before SiNₓ deposition.

Experiments were performed wherein on a silicon substrate a stack comprising a thin ALD Al₂O₃ layer (thickness 5 nm, 10 nm and 30 nm) deposited at 200° C. and a PECVD SiNₓ layer (thickness 200 nm to 300 nm) deposited at 420° C. was provided. No separate annealing step was performed between the Al₂O₃ deposition and the SiNₓ deposition. It was observed that the formation of delaminated regions is influenced by the wafer cleaning used before the Al₂O₃ deposition. In case of a hydrophilic cleaning (resulting in a hydrophilic silicon surface), the size of the delaminated regions was found to be smaller than in case of a hydrophobic cleaning (resulting in a hydrophobic silicon surface). In the experiments, hydrophilic cleaning comprises cleaning in a sulfuric-peroxide mixture (H₂O₂:H₂SO₄ 1:4 at 85° C.) followed by a 2% HF dip, cleaning in NH₄OH:H₂O₂:H₂O 1:1:5 at ambient temperature, and finally drying. Hydrophobic cleaning comprises cleaning in a sulfuric-peroxide mixture (H₂O₂:H₂SO₄ 1:4 at 85° C.), followed by a 2% HF dip and drying. It was also observed that the size of the delaminated regions increases with increasing Al₂O₃ thickness. This is illustrated in Table 1, showing the size of the delaminated regions for the different cleanings and for different Al₂O₃ thicknesses.

TABLE 1

| | 5 nm Al₂O₃ | | 10 nm Al₂O₃ | | 30 nm Al₂O₃ | |
|---|---|---|---|---|---|---|
| hydrophobic cleaning | 0 to 5 | μm | 5 to 15 | μm | 15 to 30 | μm |
| hydrophilic cleaning | 0 to 0.5 | μm | 0.5 to 1.5 | μm | 1.5 to 3 | μm |

Thus, it can be concluded that the size of the delaminated regions can be tuned by the surface pre-treatment, the ALD Al₂O₃ layer thickness and the post-deposition annealing conditions.

In one embodiment, the size (diameter) of the delaminated regions may be in the range between about 10 micrometer and 40 micrometer. The delaminated regions may cover about 2% to 5% of the total rear surface. Therefore it is preferred to perform a hydrophobic cleaning of the silicon surface before Al₂O₃ deposition. In certain embodiments the surface passivation layer is a stack comprising an Al₂O₃ layer with a thickness in the range between about 5 nm and 15 nm and a SiNₓ layer with a thickness of at least about 100 nm, the SiNₓ layer being deposited at a temperature in the range between about 400° C. and 600° C. such the need for a thermal treatment or annealing after Al₂O₃ deposition and before SiNₓ deposition can be avoided. In other embodiments the surface passivation layer can for example be an Al₂O₃ layer with a thickness of at least about 30 nm and a thermal treatment step is performed at a temperature in the range between about 400° C. and 600° C. after Al₂O₃ deposition, preferably in a nitrogen atmosphere.

Although the results described above are related to a passivation layer comprising an Al₂O₃ layer deposited by means of thermal ALD, similar bubble formation was found for Al₂O₃ layers deposited by other techniques, such as for example Plasma Enhanced ALD or Plasma Enhanced CVD. The bubbles appear due to stress build up in the Al₂O₃ layer (indicated by the behavior depending on thickness and temperature) and by hydrogen release in the Al₂O₃ layer upon thermal treatment.

Using a fabrication process in accordance with one embodiment, the number of process steps for photovoltaic cells with local back contact, e.g. PERC cells, can be reduced as compared to prior art methods. More in particular, the step of making openings in the rear side passivation layer before rear side metallization can be eliminated. As compared to a photovoltaic cell with a full Al BSF, only one additional process step (depositing the surface passivation layer at the rear side) is needed for a gain in efficiency. This is schematically illustrated in FIG. 8, showing process flows for a fabrication process in accordance with one embodiment (random Al BSF), a fabrication process for a photovoltaic cell with a full Al BSF and a prior art fabrication process for a photovoltaic cell with local Al BSF involving opening of the rear side passivation layer (e.g. by laser ablation) before rear side metallization.

Experiments were performed wherein photovoltaic cells (size 148.25 cm²) were fabricated on p-type silicon substrates according to a method of one embodiment.

As a reference, p-type silicon photovoltaic cells with a full back surface field (BSF), i.e. a BSF extending over the entire rear surface of the cells, were fabricated. For these reference cells, the front side of the substrate was textured and the rear side of the substrate was polished. An emitter was formed at the front side by POCl₃ diffusion, followed by deposition of a SiNₓ antireflection coating (ARC) at the front side. Next an Al layer was screen printed at the rear side and an Ag pattern was screen printed at the front side, followed by a metal co-firing step. The co-firing step results in the formation of an Al BSF at the rear side of the cells. The current-voltage characteristics under AM1.5 illumination obtained for these reference cells are shown in Table 2.

TABLE 2

| | J_{sc} | V_{oc} | FF | Efficiency |
|---|---|---|---|---|
| | [mA/cm2] | [mV] | [%] | [%] |
| average 3 cells | 35.6 | 622.0 | 75.1 | 16.6 |
| best cell | 35.7 | 623.5 | 75.7 | 16.8 |

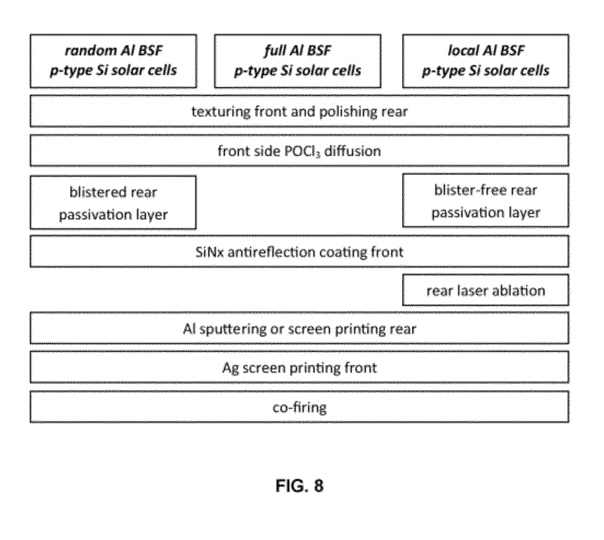

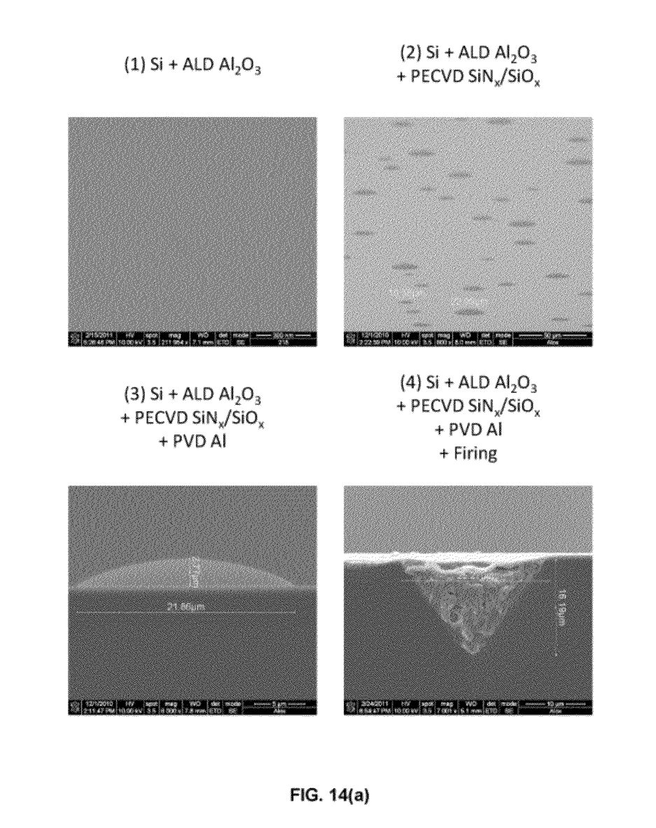

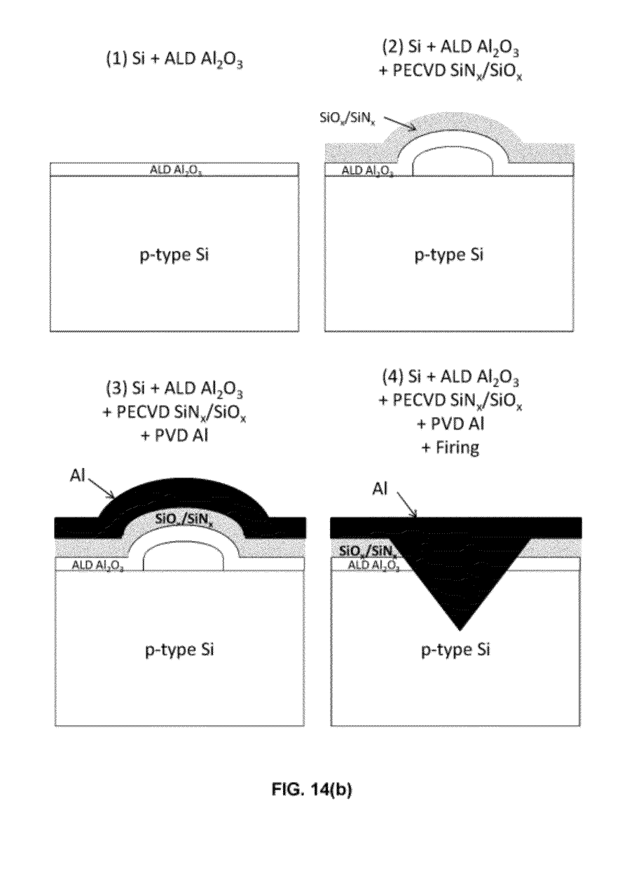

Photovoltaic cells were fabricated according to a method of one embodiment. The same process steps as used for fabricating the reference cells were used, except for one additional step. This additional step comprises depositing an Al₂O₃/SiNₓ passivation stack at the rear side of the cells, after the emitter diffusion and before the deposition of the antireflection coating. Before the deposition of the passivation stack a hydrophobic cleaning as described above was performed. In the experiments performed, the step of depositing a passivation stack comprised: depositing a first layer of ALD Al₂O₃ at about 200° C. and depositing a second layer of PECVD SiN_{*} at about 420° C. on the first layer. The thickness of the Al₂O₃ layer was about 5 nm, 10 nm or 30 nm. The thickness of the SiNₓ layer was in the range between about 200 nm and 300 nm. Instead of screen printing the Al layer at the rear side as for the reference cells, the Al layer at the rear side was provided by sputtering. The Al layer was provided over the entire rear surface of the cell, without making openings in the rear surface passivation stack. For the metal co-firing step, different temperatures were used: 845° C., 865° C. and 885° C. At locations where the passivation stack is delaminated, local point contacts and a local BSF were formed after firing, as illustrated in the SEM cross section of FIG. 7. This mechanism is also schematically illustrated in FIG. 10. FIG. 10(a) shows the situation before firing, wherein a blister 1 is formed between the surface of the silicon substrate 2 and a passivation layer 3 covered with an Al layer 4. FIG. 10(b) shows the situation after firing, wherein the Al layer 4 forms a contact to the silicon substrate 2, including a BSF region 5. Also FIGS. 14(a) and 14(b) illustrate a process flow according to one embodiment wherein contacts are formed at the location of blisters in the passivation layer. FIG. 14(a) shows SEM images of real samples, while FIG. 14(b) is a schematic representation of the same flow.

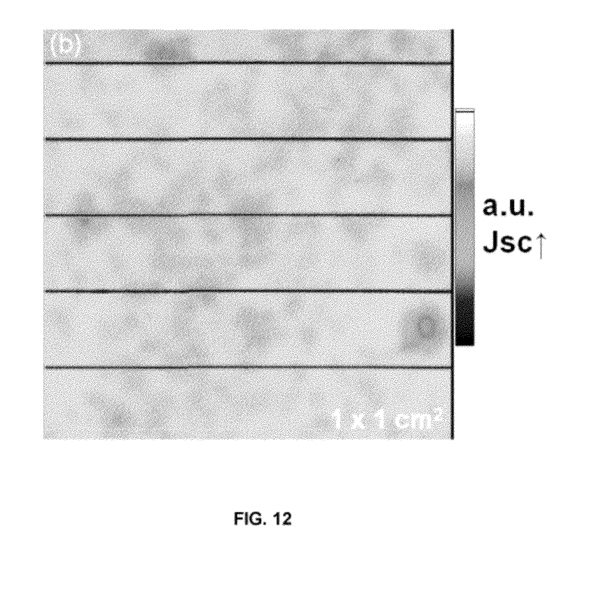

FIG. 12 shows a LBIC mapping of a random Al BSF solar cell part, clearly showing the random metal semiconductor contacts at the rear (20 μm resolution).

The current-voltage characteristics under AM1.5 illumination obtained for these cells fabricated according to a method of one embodiment are shown in Table 3. From these results it can be concluded that, especially for the cells with the smallest Al₂O₃ layer thickness (about 5 nm) and for the cells with the largest Al₂O₃ layer thickness (about 30 nm) the Fill Factor is rather low. This may be related to non-optimal contacting at the rear side of the cells, for example related to a too low bubble density or to too small bubbles. In one embodiment, best results are obtained with an Al₂O₃ layer thickness of about 10 nm, showing higher short-circuit densities J_{sc} and higher open-circuit voltages V_{oc}, as compared to the reference cells with a full BSF (Table 2) and with good Fill Factor values.

TABLE 3

| | | | | |
|---|---|---|---|---|
| Al₂O₃ | | | | |
| thickness | J_{sc} | V_{oc} | FF | Efficiency |
| [nm] | [mA/cm2] | [mV] | [%] | [%] |

Metal co-firing at 845° C.

| | | | | | |
|---|---|---|---|---|---|
| 5 | average | 29.5 | 634.8 | 40.5 | 7.6 |
| 5 | best cell | 29.5 | 634.8 | 40.5 | 7.6 |
| 10 | average | 36.5 | 629.5 | 72.3 | 16.6 |
| 10 | best cell | 36.9 | 630.3 | 72.5 | 16.8 |
| 30 | average | 36.1 | 636.3 | 63.9 | 14.7 |
| 30 | best cell | 37.3 | 634.7 | 66.7 | 15.8 |

Metal co-firing at 865° C.

| | | | | | |
|---|---|---|---|---|---|
| 5 | average | 37.4 | 632.1 | 70.2 | 16.6 |
| 5 | best cell | 37.4 | 632.1 | 70.2 | 16.6 |
| 10 | average | 36.9 | 627.9 | 74.8 | 17.3 |
| 10 | best cell | 36.9 | 626.3 | 75.4 | 17.4 |
| 30 | average | 37.1 | 635.6 | 69.1 | 16.3 |
| 30 | best cell | 37.1 | 636.3 | 71.0 | 16.7 |

Metal co-firing at 885° C.

| | | | | | |
|---|---|---|---|---|---|
| 5 | average | 36.3 | 618.7 | 73.6 | 16.6 |
| 5 | best cell | 36.6 | 619.9 | 73.6 | 16.7 |
| 10 | average | 36.5 | 623.7 | 74.6 | 17.0 |
| 10 | best cell | 36.2 | 624.4 | 75.2 | 17.0 |
| 30 | average | 36.6 | 633.5 | 67.9 | 15.8 |
| 30 | best cell | 37.1 | 632.2 | 71.1 | 16.7 |

Further results will be described now, which may partially overlap with any of the above mentioned results.

In the experiments, 148.25 cm² large photovoltaic cells were fabricated on 150 μm thick p-type silicon substrates having a resistivity of 2 Ω·cm. An emitter with a sheet resistance of 60 Ohm per square was formed at the front side of the substrates. In the case of random local Al BSF cells, a blistered layer was used as rear surface passivation without any additional contact opening step. Full Al BSF cells and blister-free local Al BSF cells with laser ablation of the rear passivation layer were used as references. FIG. 8 schematically illustrates the process flows for the different cells.

Before deposition of a rear side passivation layer, the wafers were cleaned either with a HF-last (Si—H) step or an oxidizing (Si—OH) last step, followed by Marangoni drying, known to the skilled person.

As rear surface passivation layer for the random Al BSF cells and the local Al BSF cells, a stack of ALD Al₂O₃ and PECVD SiNₓ was used. Thermal ALD Al₂O₃ films of 5 nm, 10 nm or 30 nm thickness were grown at 200° C. in a commercial ALD reactor using trimethylaluminium (TMA) and de-ionized (DI) water as precursors. The SiNₓ layer thickness was optimized for the rear internal reflectance in the solar cells. The co-firing process step was performed at 845° C., 865° C. or 885° C. for the cells with random Al BSF and at 865° C. for the local Al BSF and full Al BSF cells.

Blistering was visualized and measured with a scanning electron microscope (SEM) or optical microscope. The used current-voltage (I—V) setup is a steady-state Xe lamp solar simulator with an illuminated area of 200×200 mm², a small bias error and a good stability over time. Spatially resolved series resistance of silicon solar cells was measured using a commercial photoluminescence (PL) system. An in-house assembled light beam induced current (LBIC) measurement setup was used to map the short circuit current density (J_{sc}) of the solar cells at a wavelength of 1050 nm.

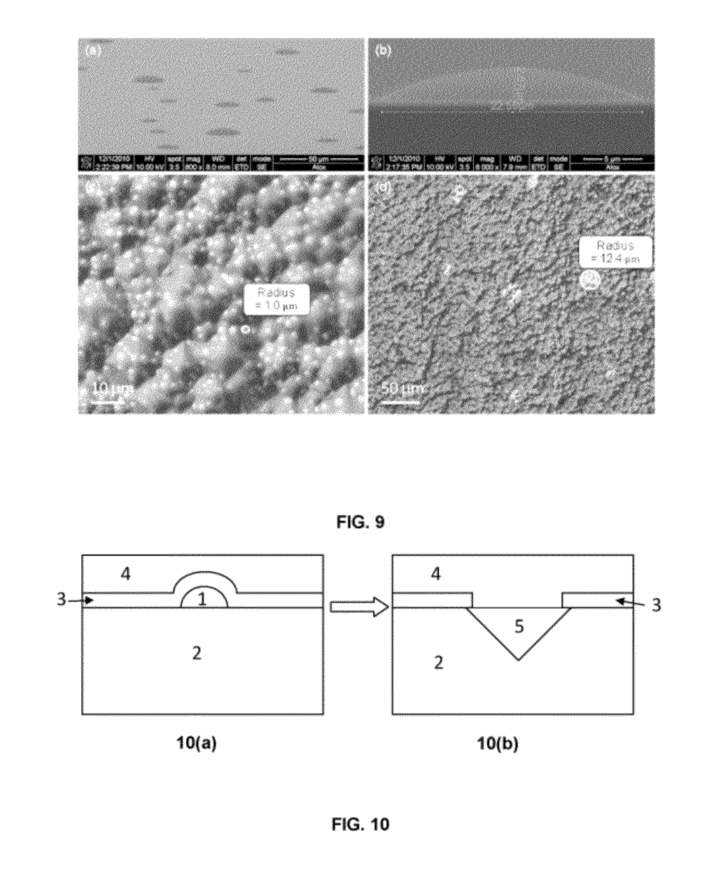

Blistering of the ALD Al₂O₃/PECVD SiNₓ passivation layers was observed. Blistering is the partial delamination of a thick enough (thickness for instance larger than or equal to 10 nm, e.g. larger than or equal to 30 nm) Al₂O₃ layer caused by gaseous desorption in the Al₂O₃ film upon thermal treatments above a critical temperature (e.g. about 400° C. to 600° C.). The Al₂O₃ layer acts as a gas barrier and bubble formation occurs. Capping the Al₂O₃ layer with a SiOₓ layer or a SiNₓ layer also results in blistering: the capping layer is deposited at temperatures above the critical temperature for blistering, and in addition the total stack is a more efficient gas barrier than a single Al₂O₃ layer. SEM pictures of typical blistered Al₂O₃/SiNₓ stacks deposited on Si are shown in FIG. 9(a) and FIG. 9(b).

The pre-ALD cleaning has an influence on blister formation. It was observed that hydrophilic cleaning leads to a larger density of smaller blisters, while hydrophobic cleaning leads to a smaller density of larger blisters, as can be seen in FIG. 9(c) and FIG. 9(d), respectively. FIG. 9(c) and FIG. 9(d) are optical microscopy top-view pictures of an ALD Al₂O₃/PECVD SiNₓ layer grown on a rough c-Si surface, for a hydrophilic pre-ALD deposition clean (FIG. 9(c)) and for a hydrophobic pre-ALD deposition clean (FIG. 9(d)).

Using a sufficiently thin Al₂O₃ layer and performing an annealing step e.g. at a temperature above 600° C. prior to SiNₓ capping can be performed to avoid blistering. The Al₂O₃ layer is out-gassed prior to SiNₓ capping layer deposition and it can still have adequate passivation properties. This was done to prepare the local Al BSF reference cells where laser ablation was used to open the rear dielectric passivation layer prior to metallization.

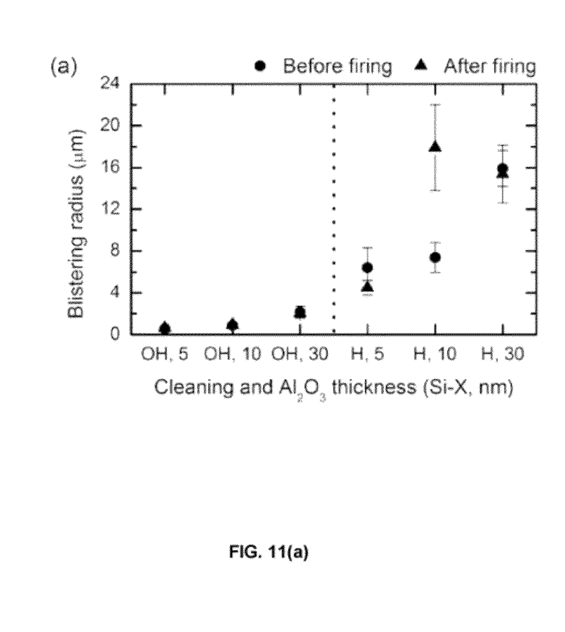

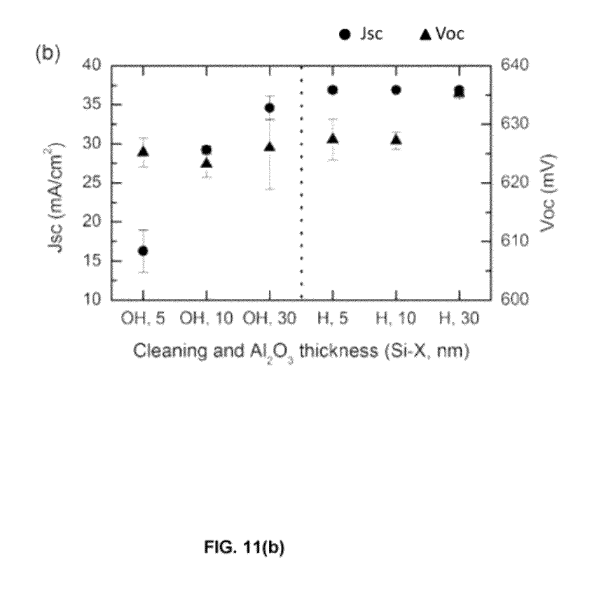

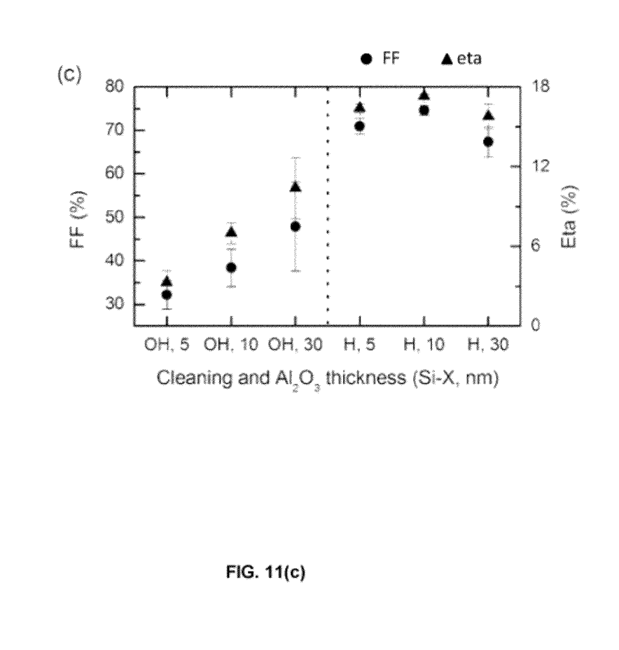

Random Al BSF solar cells were fabricated wherein blisters were formed at the interface between the silicon substrate and the stack of Al₂O₃ and SiNₓ in accordance with one embodiment. Hydrophilic as well as hydrophobic pre-ALD cleaning were used and 5 nm, 10 nm or 30 nm thick Al₂O₃ layers were deposited. The average size of the blisters at the silicon/Al₂O₃ interface varied as shown in FIG. 11(a). This average size was measured before and after the co-firing step. After the firing step, the rear Al metal layer of the random Al BSF cells was removed in hot HCl to revisualize the blistering. The averages of short-circuit current density (J_{sc}), open-circuit voltage (V_{oc}), fill factor (FF) and energy conversion efficiency (eta) for the random local Al BSF cells fired at 865° C. are given in FIGS. 11(b) and FIG. 11(c).

From FIG. 11(a,b,c) it can be concluded that a minimum blister radius, e.g. a blister radius larger than 4 micrometer, preferably larger than 5 micrometer is advantageous to enable sufficient contacting and consequently a sufficiently high FF and J_{sc}. The best FF and J_{sc} were obtained when the blistering size still increases during firing, which was the case for a 10 nm thick Al₂O₃ layer and a hydrophobic pre-ALD cleaning. The hydrophilic pre-ALD cleaning is less favorable since the blistering size is too low and the density too high, as for example illustrated in FIG. 9(c) and reflected in a lower FF, J_{sc} and V_{oc}. On the other hand a thickness of 10 nm for the Al₂O₃ layer (a thickness for instance in the range of 5 nm to 20 nm, more preferably 7 nm to 15 nm) is a favorable thickness since it is not too thick to cause blistering on itself (as compared to e.g. a 30 nm thick Al₂O₃ layer) and it is thick enough to allow sufficient additional out-gassing during the firing process. SEM measurements clearly show that local BFS regions are created upon firing of a blistered rear passivation layer covered by a metal, as illustrated in FIG. 7. LBIC measurements illustrate the random distribution of these local contacts as darker regions where the J_{sc} is reduced, as illustrated in FIG. 12.

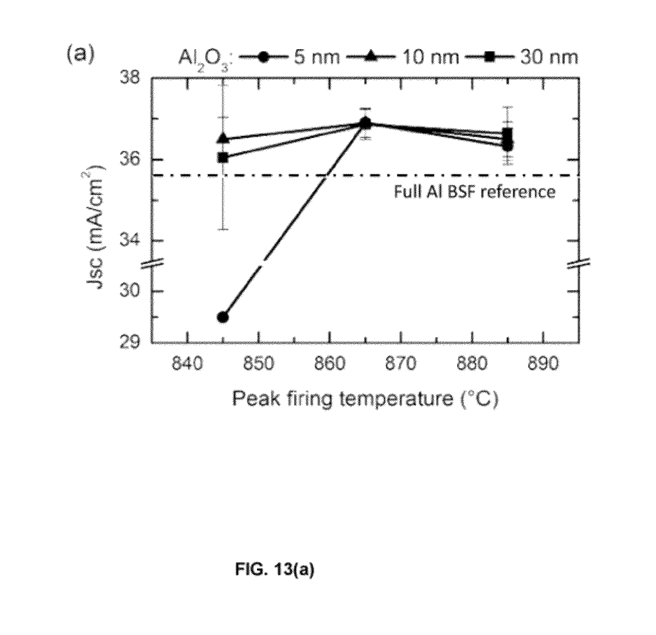

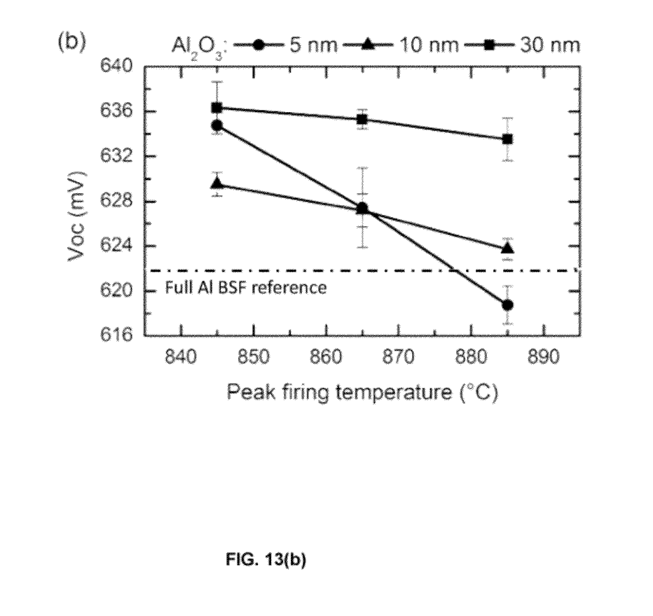

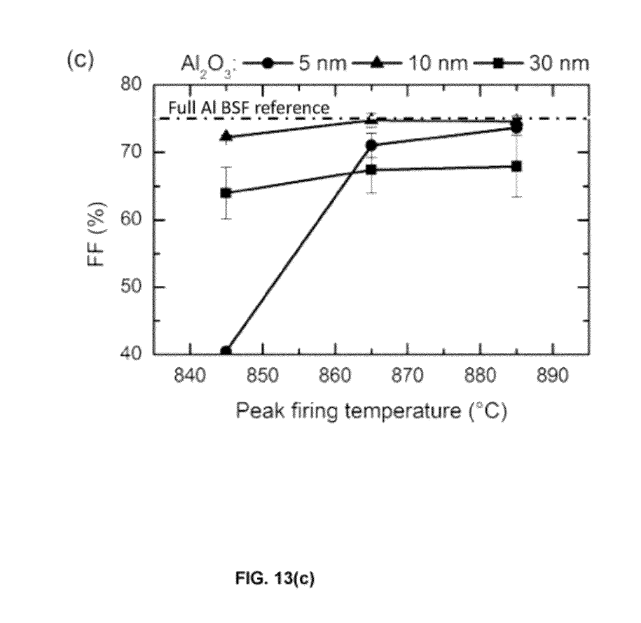

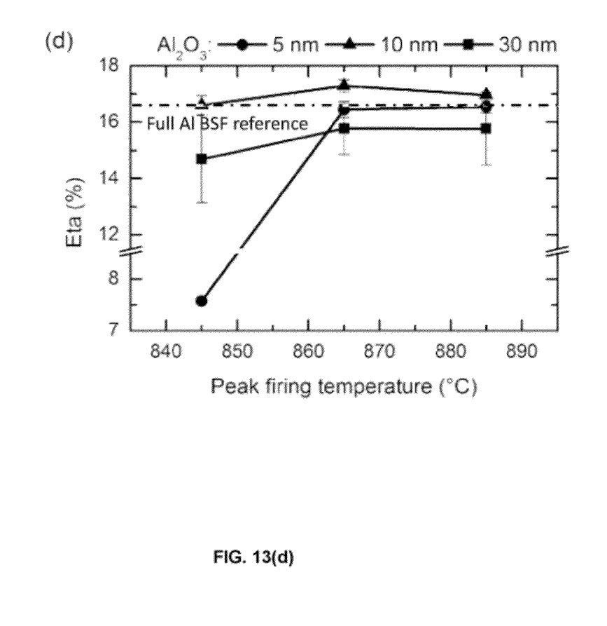

For random Al BSF cells with hydrophobic cleaning prior to ALD Al₂O₃ deposition the blistering size is large enough to enable sufficient contacting. Average values of J_{sc}, V_{oc}, FF and efficiency as a function of peak firing temperature are shown in FIGS. 13(a), 13(b), 13(c) and 13(d) respectively. It can be concluded that there is a balance between passivation quality and contacting as a function of the peak firing temperature. If the firing temperature is too high, the rear surface passivation quality or the open-circuit voltage V_{oc} may decrease too much. On the other hand, if the peak firing temperature is too low, the rear contacting or FF (and hence J_{sc}) may not be optimal.

The best random Al BSF cells had an average cell efficiency of 17.4% compared to 16.6% for full Al BSF reference cells. There is an apparent gain in J_{sc} and V_{oc}, of 1.3 mA/cm² and 5 mV respectively, because of a better rear internal reflection and better rear surface passivation. In a separate experiment, also blister-free local Al BSF cells were fabricated. The results suggest that potentially a gain in V_{oc} of 14.2 mV could be achievable for the random Al BSF cells compared to full Al BSF cells. The gap in V_{oc} between the best Al₂O₃/SiNₓ passivated random and local Al BSF cells may have several reasons. In the case of the hydrophobic pre-ALD cleaning, during firing a large density of smaller blisters is created. These additional blisters may or may not lead to additional contacting, but it causes a lower V_{oc} in both cases because of a reduced surface passivation quality. The blistering density is not uniform and it is clearly lower at the edges of a Si wafer. This may lead to an increased cell series resistance at the edge of random Al BSF cells compared to full Al BSF cells. The formation of additional tiny blisters can be avoided by performing an annealing step between the Al₂O₃ deposition step and the SiNₓ deposition step. This annealing step is preferably performed at a temperature that is sufficiently high to outgas the Al₂O₃ film just enough to avoid the creation of these additional blisters during firing. However this annealing step is preferably performed at a temperature that is low enough to leave the opportunity of a minor size increase during firing for the already existing blisters. By comparing the formation of blisters on minor polished wafers to textured wafers, it was observed that blisters appear easier in the vicinity of surface features. This effect can be used to compensate for the lower blistering density at the edge of wafers.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention.

What is claimed is:

1. A method of fabricating a photovoltaic cell comprising local back contacts, the method comprising:
providing a silicon substrate;
depositing a surface passivation layer at a rear side of the silicon substrate;
forming delaminated regions at an interface between the surface passivation layer and the silicon substrate;
depositing a metal layer on the surface passivation layer; and
performing a metal firing process.

2. The method according to claim 1, wherein forming delaminated regions at an interface between the surface passivation layer and the silicon substrate comprises:
cleaning the silicon substrate using a hydrophobic cleaning process;
depositing the surface passivation layer at a rear side of the silicon substrate after the hydrophobic cleaning; and
performing a thermal treatment.

3. The method according to claim 1, wherein depositing the surface passivation layer comprises depositing a surface passivation layer having a thickness of at least about 30 nm.

4. The method according to claim 2, wherein performing a thermal treatment comprises performing a temperature treatment at a temperature in the range between about 400° C. and 600° C.

5. The method according to claim 2, wherein the hydrophobic cleaning comprises a cleaning process leaving a hydrophobic surface after cleaning.

6. The method according to claim 1, wherein depositing the surface passivation layer comprises depositing a stack of layers.

7. The method according to claim 6, wherein the surface passivation layer comprises a first layer comprising Al₂O₃, with a thickness in the range between about 2 nm and 30 nm, and a second layer comprising SiNₓ or SiOₓ, with a thickness in the range between about 70 nm and 300 nm.

8. The method according to claim 7, wherein the first layer is deposited at a temperature lower than about 250° C. and wherein the second layer is deposited at a temperature in the range between about 400° C. and 600° C., thereby at the same time performing the thermal treatment.

9. The method according to claim 1, wherein the metal comprises aluminum and wherein the metal firing is performed at a temperature in the range between about 835° C. and 950° C.

10. The method according to claim 7, further comprising performing an additional annealing process after depositing the first layer and before depositing the second layer, the additional annealing being performed at a temperature in the range between about 600° C. and 900° C.

11. A photovoltaic cell fabricated by the method according to claim 1.

12. A photovoltaic device having a rear surface and a front surface, the photovoltaic device comprising:
a silicon substrate;
a surface passivation layer at a rear side of the silicon substrate; and
local back contacts;
wherein the local back contacts are randomly distributed on the rear surface of the photovoltaic device.

13. The photovoltaic device according to claim 12, wherein the passivation layer comprises delaminated regions at positions corresponding to the local back contacts.

14. The photovoltaic device according to claim 12, wherein the passivation layer has a thickness of at least about 30 nm.

15. The photovoltaic device according to claim 14, wherein the passivation layer comprises a first layer comprising Al₂O₃, with a thickness in the range between about 2 nm and 30 nm, and a second layer comprising SiNₓ or SiOₓ, with a thickness in the range between about 70 nm and 300 nm.

16. The photovoltaic device according to claim 12, wherein the local back contacts comprise aluminum.
